(19) United States
(12) Patent Application Publication
(10) Pub. No.: US 2023/0082571 A1
(43) Pub. Date: Mar. 16, 2023

(54) POWER SEMICONDUCTOR DEVICE AND METHOD OF PRODUCING POWER SEMICONDUCTOR DEVICE

(71) Applicant: Infineon Technologies AG, Neubiberg (DE)

(72) Inventors: Jochen HILSENBECK, Villach (AT); Thomas SOELLRADL, Feldkirchen (AT); Roman ROTH, Sattendorf (AT); Annette SAENGER, Dresden (DE); Ulrike FASTNER, Villach (AT); Johanna SCHLAMINGER, Villach (AT); Joachim HIRSCHLER, Villach (AT); Andreas BEHRENDT, Villach (AT)

(21) Appl. No.: 17/945,494

(22) Filed: Sep. 15, 2022

(30) Foreign Application Priority Data
Sep. 16, 2021 (DE) 102021124003.4

(51) Int. Cl. H01L 23/00; H01L 23/31

(52) U.S. Cl. CPC H01L 24/05; H01L 24/03; H01L 23/3192; H01L 2224/03462; H01L 2224/03614; H01L 2224/05023; H01L 2224/05082

(57) ABSTRACT

A power semiconductor device includes a semiconductor body and a first terminal at the semiconductor body. The first terminal has a first side for adjoining an encapsulation and a second side for adjoining the semiconductor body. The first terminal includes, at the first side, a top layer; and, at the second side, a base layer coupled with the top layer, wherein a sidewall of the top layer and/or a sidewall of the base layer is arranged in an angle smaller than 85° with respect to a plane.

### RELATED APPLICATION

This application claims priority to German Patent Application No. 102021124003.4, filed on Sep. 16, 2021, entitled “Power Semiconductor Device Method of producing a Power Semiconductor Device”, which is incorporated by reference herein in its entirety.

### TECHNICAL FIELD

This specification refers to embodiments of a power semiconductor device and to embodiments of a method of producing a power semiconductor device. For example, the specification relates to embodiments of a power semiconductor device having a terminal structure specifically configured with respect to the coupling with an encapsulation, and to embodiments of a corresponding method.

### SUMMARY

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device may comprise a semiconductor body, e.g., comprising silicon (Si) or silicon carbide (SiC), and configured to conduct a forward load current along a load current path between two load terminals of the device.

Further, in case of a controllable power semiconductor device, e.g., a transistor, the load current path may be controlled by means of an insulated electrode, commonly referred to as gate or control electrode. For example, upon receiving a corresponding control signal from, e.g., a driver unit, the control electrode may set the power semiconductor device in one of a forward conducting state and a blocking state. In some cases, the gate electrode may be included within a trench of the power semiconductor switch, wherein the trench may exhibit, e.g., a stripe configuration or a needle configuration.

Some power semiconductor devices further provide for a reverse conductivity; during a reverse conducting state, the power semiconductor device conducts a reverse load current. Such devices may be designed such that the forward load current capability (in terms of magnitude) is substantially the same as the reverse load current capability. In some examples, a device that provides for both forward and reverse load current capability may be a MOSFET with an integrated body diode or the reverse conducting (RC) IGBT.

After the wafer has been processed and the chips have been diced out, the chips may be installed in a package to form a power semiconductor device module. Within the module, the load terminals and the control terminals must be electrically contacted. To ensure insulation between the load and control terminals and/or to provide for an environmental sealing, the chips may be covered with an encapsulation, e.g., comprising imide and/or dielectric layer stacks, within the package.

The present specification is directed to the coupling between the terminal(s) and the encapsulation. It is a design goal of the present application to ensure a reliable and safe coupling between the terminal(s) and the encapsulation.

Herein, the term “encapsulation” refers to the electrically insulating structure used for covering the terminal(s) that, e.g., comprise a metal and/or another electrically conducting material. Thus, for example, the term “encapsulation” may likewise refer to a “passivation” or any other insulating material used to form of the electrically insulating structure.

According to an embodiment, a power semiconductor device comprises a semiconductor body and a first terminal at the semiconductor body (e.g., the first terminal may be coupled to the semiconductor body). The first terminal has a first side for adjoining an encapsulation and a second side for adjoining the semiconductor body. The first terminal comprises, at the first side, a top layer; and, at the second side, a base layer coupled with the top layer, wherein a sidewall of the top layer and/or a sidewall of the base layer is arranged in an angle smaller than 85° with respect to a plane (e.g., a horizontal plane).

According to an embodiment, a power semiconductor device comprises a semiconductor body and a first terminal at the semiconductor body (e.g., the first terminal may be coupled to the semiconductor body). The first terminal has a first side for adjoining an encapsulation and a second side for adjoining the semiconductor body. The first terminal comprises a layer stack of at least two layers, wherein a transition between a sidewall of an upper layer of the at least two layers and a surface portion of a lower layer of the at least two layers occurs at an angle greater than 95° with respect to a plane (e.g., a horizontal plane).

According to an embodiment, a method of producing a power semiconductor device comprises: forming a semiconductor body and forming a first terminal over the semiconductor body (e.g., the first terminal may be coupled to the semiconductor body). The first terminal has a first side for adjoining an encapsulation and a second side for adjoining the semiconductor body. The first terminal comprises, at the first side, a top layer; and, at the second side, a base layer coupled with the top layer, wherein a sidewall of the top layer and/or a sidewall of the base layer is arranged in an angle smaller than 85° with respect to a plane (e.g., a horizontal plane).

According to an embodiment, a method of producing a power semiconductor device comprises: forming a semiconductor body and forming a first terminal over the semiconductor body (e.g., the first terminal may be coupled to the semiconductor body). The first terminal has a first side for adjoining an encapsulation and a second side for adjoining the semiconductor body. The first terminal comprises a layer stack of at least two layers, wherein a transition between a sidewall of an upper layer of the at least two layers and a surface portion of a lower layer of the at least two layers occurs at an angle greater than 95° with respect to a plane (e.g., a horizontal plane).

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a vertical cross-section of a power semiconductor device in accordance with one or more embodiments;

FIG. 2 schematically and exemplarily illustrates a section of a vertical cross-section of a power semiconductor device in accordance with one or more embodiments;

FIGS. 3 to 10 schematically and exemplarily illustrate, based on a respective a section of a vertical cross-section of a power semiconductor device, a power semiconductor device production method in accordance with one or more embodiments; and

FIG. 11 schematically and exemplarily illustrates a section of a vertical cross-section of resist layer used in a method of producing a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing acts have been designated by the same references in the different drawings if not stated otherwise.

The term “horizontal” as used in this specification intends to describe an orientation substantially parallel to a mean horizontal surface of a semiconductor substrate or of a semiconductor structure. This can be for instance the surface of a semiconductor wafer or a die or a chip or, respectively, of a virtual plane on top of a surface that is not entirely flat (e.g., in case of a silicon carbide (SiC) based semiconductor body). For example, both the first lateral direction X and the second lateral direction Y mentioned herein can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of said surface. For example, the vertical direction Z mentioned herein may be an extension direction that is perpendicular to both the first lateral direction X and the second lateral direction Y.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device. Further, in the context of the present specification, the term “in contact” intends to describe that there is a direct physical connection between two elements of the respective semiconductor device; e.g., a transition between two elements being in contact with each other does not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

Some embodiments described in this specification pertain to a power semiconductor device, such as an Insulated Gate Bipolar Transistor (IGBT), a reverse conducting (RC) IGBT, a field effect transistor (e.g., a Metal Oxide Semiconductor Field Effect Transistor (MOSFET), Fin Field Effect Transistor (FinFET), Junction-gate Field Effect Transistor (JFET)), a diode or derivatives thereof, e.g., a power semiconductor device to be used within a power converter or a power supply. Thus, in an embodiment, such power semiconductor device can be configured to carry a load current that is to be fed to a load and/or, respectively, that is provided by a power source. For example, the power semiconductor device may comprise a plurality of power semiconductor cells, such as monolithically integrated diode cells, derivatives of a monolithically integrated diode cell, monolithically integrated MOSFET or IGBT cells and/or derivatives thereof. Such diode/transistor cells may be integrated in a power semiconductor module. A plurality of such cells may constitute a cell field that is arranged within an active region of the power semiconductor device. The term “power semiconductor device” as used in this specification intends to describe a power semiconductor device on a single chip with high voltage blocking and/or high current-carrying capabilities. In other words, embodiments of the power semiconductor device described herein are single chip power semiconductor devices configured for high current, which may be in the Ampere range, e.g., up to one or more Amperes and/or up to one or more tens or hundreds of Amperes, and/or high voltages, which may be 200 volts (V) and above, e.g., at least 400 V or even more, e.g., at least 2 kV, or even above 6 kV or more.

For example, the power semiconductor device described below may be a single chip power semiconductor device configured to be employed as a power component in a low-, medium- and/or high voltage application. Several single chip power semiconductor device may be integrated in a module so as to form a power semiconductor device module, e.g., for installation and use in a low-, medium- and/or high voltage application, such as a major home appliance, a general purpose drive, an electric-drive train, a servo drive, a traction, a (higher) power transmission facilities, etc.

In some examples, the term “power semiconductor device” as used in this specification is not directed to a logic semiconductor device used for, e.g., storing data, computing data and/or other types of semiconductor-based data processing.

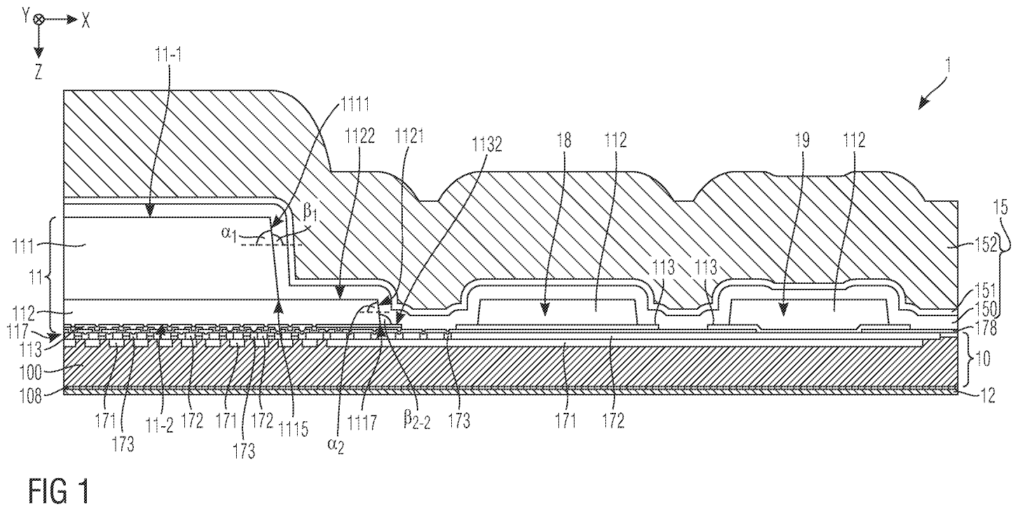

FIG. 1 schematically and exemplarily illustrates a section of a vertical cross-section of a power semiconductor device 1, herein also simply referred to as device 1, in accordance with one or more embodiments.

The device 1 comprises a semiconductor body 10 and, coupled thereto, a first terminal 11 and a second terminal 12. Both terminals 11 and 12 may be load terminals. In such case, the device 1 can be configured for conducting a load current between the first load terminal 11 and the second load terminal 12. The first load terminal 11 may be arranged at a frontside. The second load terminal 12 may be arranged at a backside of the device.

In another (non-illustrated) case, the first terminal 11 may be a control terminal, e.g., a gate terminal.

For example, when being installed in a package (not illustrated), the power semiconductor device 1 is mounted such that its backside rests on a floor of the package, whereas the frontside and the first terminal 11 face to the interior of the package. As described in the foregoing description, the first terminal 11 (and, if present, further terminals and/or runners) at the frontside can at least partly be covered with an encapsulation 15 to ensure terminal insulation and environmental sealing. For example, the first terminal 11 (and, if present, further terminals) may be partly or fully covered with the encapsulation 15. For example, a first side 11-1 of the first terminal 11 adjoins the encapsulation 15, and a second side 11-2 of the first terminal 11 adjoins the semiconductor body 10, e.g., via a contact plug structure 117.

The semiconductor body 10 can exhibit any configuration, such as a diode configuration, a FET configuration (e.g., MOSFET, FinFET, JFET), an IGBT configuration or a derivate thereof. According to the configuration, the semiconductor body 10 may comprise several doped regions. These designs are principally known to the skilled person and will hence not described herein in more detail.

For example, the semiconductor body 10 may comprise several doped regions 171, 172 and 173 at the frontside. For example, the doped regions 171 and 172 are of the second conductivity type, and the doped regions 173 are of the first conductivity type. E.g., at least the doped regions 172 are electrically connected with the first terminal 11 via the contact plug structure 117 that locally penetrates an insulation layer 178.

The major portion of the semiconductor body 10 is formed by a drift region 100 of the first conductivity type. The drift region 100 extends along the vertical direction Z until adjoining a doped region 108 also of the first conductivity type, but exhibiting a greater dopant concentration as compared to the drift region 100. The doped region 108 may be a buffer region (e.g., in the case of a MOSFET) or a field stop region (e.g., in the case of an IGBT). The doped region 108 is electrically connected to the second terminal 12.

FIG. 1 illustrates, in its left portion, a section of an active region of the device 1 where power cells are arranged in accordance with a specific pattern in the semiconductor body 10, e.g., including said doped regions 171, 172, 173. The arrangement of the doped regions 171, 172 and 173 as illustrated in FIG. 1 is only exemplary. Other arrangement may be provided. For example, the configuration of the first terminal 11 as described below may be chosen irrespective of the arrangement of the doped regions (e.g., the regions 171, 172 and 173) in the semiconductor body 10.

The active region is surrounded by an edge termination region, which is illustrated in the right portion of FIG. 1. In the edge termination structure, the cell structure is not implemented, as the edge termination structure may fulfill other functions than load current conduction.

In some examples, in the edge termination region, there may be arranged further terminals, such as a control runner 18 and a source runner 19. For example, the source runner 19 exhibits the same electrical potential as the first terminal 11, if the first terminal is one of the load terminals of the device 1. The control runner 18 may be electrically insulated from the first terminal 11. In some examples, the device 1 is a controllable device which can be switched between a forward-conducting state and a forward-blocking state based on a control signal that is generated by applying a voltage between the first terminal 11 and a control terminal (not illustrated) that is electrically connected with the control runner 18.

The semiconductor body 10 may comprise (e.g., be based on) semiconductor material. In an embodiment, the semiconductor material is a wideband semiconductor material, e.g., having a bandgap above that of silicon (−1.1 electronvolts (eV)) or above 2 eV or even above 3 eV. In an embodiment, the semiconductor material is silicon carbide (SiC). Other embodiments may use a III-V compound semiconductor material, e.g., gallium nitride (GaN), as a semiconductor material. Using a wide bandgap material offers the possibility for higher switching frequencies at lower losses leading to a significant improvement in system efficiency, in accordance with one or more embodiments. Further, the wider bandgap allows for a significant shrinkage of the edge termination region and thereby overall chip area leading to an increased current density on package level, in accordance with one or more embodiments. Such devices enable a higher power density on system level at a smaller footprint compared to silicon devices, in accordance with one or more embodiments.

The present specification is not primarily directed to the configuration of the semiconductor body 10, but to (i) the configuration(s) of the first terminal 11 (and, if present, further terminals such as the the runners 18 and 19) and (ii) the coupling between the first terminal 11 (and, if present, the runners 18 and 19) and the encapsulation 15. Hence, it shall be understood that the configuration of the semiconductor body 10 illustrated in FIG. 1 and briefly described above is only one example, and that the description below related to (i) the configuration(s) of the first terminal 11 (and, if present, further terminals such as the runners 18 and 19) and (ii) the coupling between the first terminal 11 (and, if present, the runners 18 and 19) and the encapsulation 15 can essentially be applied to any power semiconductor device, irrespective of the configuration of its semiconductor body 10.

In an embodiment, the first terminal 11 has said first side 11-1 for adjoining the encapsulation 15, and said second side 11-2 for adjoining the semiconductor body 10. The first terminal 11 comprises, at the first side 11-1, a top layer 111; and, at the second side 11-2, a base layer 112 coupled with the top layer 111. A sidewall 1111 of the top layer 111 and/or a sidewall 1121 of the base layer 121 is arranged in an angle α₁ (or, respectively α₂) smaller than 85° with respect to a horizontal plane. Herein, the horizontal plane may be defined by the first and second lateral directions X and Y, both of which are perpendicular to the vertical direction. Hence, an angle α₁ of 90° would be in parallel to the vertical direction Z. But, as illustrated in FIG. 1, both sidewalls 1111, 1112 are “inclined” with respect of the vertical direction Z; e.g., both sidewalls may extend with said angles α₁ and α₂ smaller than 85°. Such inclination provides for a more stable coupling with the encapsulation 15.

Both angles α₁ and α₂ may be smaller than 85°, smaller than 75° or even smaller than 45°. Further, both angles α₁ and α₂ should not be greater than 90°.

In an embodiment, the top layer sidewall 1111 and/or the base layer sidewall 1121 continuously extends at said angle α₁ (or, respectively α₂) smaller than 85°, as illustrated in FIG. 1. For example, the top layer sidewall 1111 continuously extends for at least 80% of its total extension at said angle α₁ smaller than 85°. For example, the base layer sidewall 1121 continuously extends for at least 80% of its total extension at said angle α₂ smaller than 85°.

In an embodiment, the top layer sidewall 1111 and/or the base layer sidewall 1121 has a/have a respective total extension of at least 2 μm. For example, the base layer 112 has a thickness of 5 μm. The top layer 111 may be thicker than the base layer 112. In some examples, the top layer has a thickness of 15 μm. The total extensions of the sidewalls 1111 and 1121 follow from the thicknesses of the layers 111 and 112 and the chosen angles α₁ and α₂.

In an embodiment, the top layer sidewall 1111 and/or the base layer sidewall 1121 extend(s) substantially linearly, e.g., at a constant, non-varying inclination angle α₁, α₂ respectively.

The top layer 111 may be arranged in direct contact with the base layer 112. As illustrated, the base layer 112 may exhibit a greater area has compared to the top layer 111, such that the top layer 111 covers the base layer 112 only partially.

In addition, a further layer 113 may be provided as part of the first terminal 11. In some examples, the base layer 112 rests on the further layer 113, wherein the further layer 113 may exhibit a greater area has compared to the base layer 112, such that the base layer 112 covers the further layer only partially. The further layer 113 is, in an embodiment, thinner (e.g., significantly thinner) than the base layer 112.

Portions of the base layer 112 and the further layer 113 may be employed to form the control runner 18 and/or the source runner 19, as illustrated in FIG. 1.

In some examples, both the top layer 111 and the base layer 112 comprise (e.g., are based on) a metal, e.g., copper (Cu), or gold (Au). Also, the further layer 113 can comprise (e.g., be based on) a metal, such as titanium (Ti), tungsten (W) or a combination of such. In some examples, both the top layer 11 and the base layer 112 consist of a material with a copper content of at least 80 vol % or at least 90 vol %.

In some examples (according to the foregoing description, for example), the first terminal 11 may exhibit a layer stack configuration comprising, e.g., the top layer 111 resting on the base layer 112 which rests on the further layer 113. Irrespective of the choice of the angles α₁ and α₂, it may be provided that (i) a first transition 1115, between the top layer sidewall 1111 and a surface portion 1122 of the base layer 112, occurs at an angle β₂₋₂ greater than 95° (with respect to the horizontal plane, for example), and/or (ii) a second transition 1117, between the base layer sidewall 1121 and a surface portion 1132 of the further layer 113 below the base layer 112, occurs at an angle (e.g., the angle β₂₋₂) greater than 95° (with respect to the horizontal plane, for example).

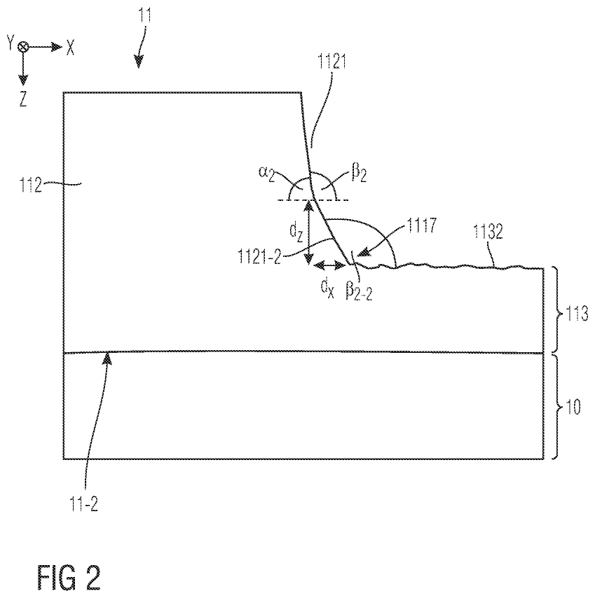

This aspect is illustrated in FIG. 1 and, for the second transition 1117, more clearly in FIG. 2. For example, the second transition 1117 has a vertical extension d_{z} of at least 400 nm (or of at least 800 nm) and a lateral extension dₓ of at least 250 nm (or of at least 400 nm). Hence, in contrast to the schematic illustration in FIG. 2, the lateral extension dₓ may be greater than the vertical extension d_{z}.

In an embodiment, the top layer sidewall 1111 has an upper portion and a lower portion, the lower portion forming said first transition 1115. Additionally or alternatively, as illustrated in FIG. 2, the base layer sidewall 1121 has an upper portion and a lower portion 1121-2, the lower portion 1121-2 forming said second transition 1117. Further, both the upper portion and the lower portion of the top layer sidewall 1111 may be arranged in a respective angle with respect to the horizontal plane, wherein the angle of the lower portion forming said first transition 1115 is greater than the angle of the upper portion. Additionally or alternatively, as illustrated in FIG. 2, both the upper portion and the lower portion of the base layer sidewall 1121 may be arranged in a respective angle β₂, β₂₋₂ with respect to the horizontal plane, wherein the angle β₂₋₂ of the lower portion 1121-2 forming said second transition 1117 is greater than the angle β₂ of the upper portion.

Such configuration of the second transition 1117 (which may likewise be provided for the first transition 1115) may reduce the mechanical stress that occurs at the coupling between the first terminal 11 and the encapsulation 15. The second transition 1117 (and/or the reduced mechanical stress) can be beneficial during the deposition of the encapsulation 15 and helps to prevent growth artefacts which could impair the tightness of the encapsulation 15. It shall be understood that corresponding transitions may be provided for the control runner 18 and the source runner 19. It shall further be understood, as explained above, that the inclination angles α₁ and α₂ of the sidewalls 1111 and 1121 may be locally modified with respect to an average inclination angle when the respective sidewall 1111/1121 forms the transition 1115/1117 with the surface portion of the lower layer 112/113. That is, the transition 1115/1117 may be formed by a corresponding configuration of the respective upper layer 111/112.

As mentioned in the foregoing description, herein, the term “encapsulation 15” refers to the insulating structure that is employed to cover the first terminal(s) 11 (and, if present, the runners 18, 19) at the frontside of the device 1. Here, several insulating materials may be used, as illustrated in FIG. 1. In some examples, the encapsulation 15 comprises (e.g., is based on) several layers, e.g., a isolating layer 150, e.g., silicon oxide (SiO2), or silicon nitride (SiN) or a combination of these and a passivation layer 151, e.g., silicon nitride (SiN), and an isolation layer 152 (e.g., a thick isolation layer), which can comprise (e.g., be based on) imide. In an embodiment, the encapsulation 15 is coupled to (e.g., is arranged at and/or adjoins) the top layer sidewall 1111 and/or the base layer sidewall 1121. For example, the isolation layer 152 covers one, some and/or all of (e.g., most of) the components arranged at the front side of the device 1, whereas another component of the encapsulation 15 may, e.g., cover only one of the top layer sidewall 1111 and the base layer sidewall 1121.

Presented herein are also methods of producing a power semiconductor device.

According to an embodiment, a method of producing a power semiconductor device comprises forming the following components: a semiconductor body and a first terminal at the semiconductor body. The first terminal has a first side for adjoining an encapsulation and a second side for adjoining the semiconductor body. The first terminal comprises, at the first side, a top layer; and, at the second side, a base layer coupled with the top layer, wherein a sidewall of the top layer and/or a sidewall of the base layer is arranged in an angle smaller than 85° with respect to a horizontal plane. For example, forming the top layer comprises: providing a resist layer; and/or processing the resist layer, such that at least one opening in the resist layer is defined by a resist layer sidewall (of the resist layer) arranged in an angle greater than 95° with respect to the horizontal plane (e.g., processing the resist layer may comprise forming the at least one opening, in the resist layer, that is defined by the resist layer sidewall arranged in said angle greater than 95° with respect to the horizontal plane). Processing the resist layer may comprise controlling a focal plane during an exposure of the resist layer for achieving the configuration of the resist layer sidewall at said angle greater than 95° with respect to the horizontal plane (e.g., the focal plane may be controlled during the exposure of the resist layer to form the resist layer sidewall at said angle greater than 95° with respect to the horizontal plane).

According to an embodiment, a method of producing a power semiconductor device comprises forming the following components: a semiconductor body and a first terminal at the semiconductor body. The first terminal has a first side for adjoining an encapsulation and a second side for adjoining the semiconductor body. The first terminal comprises a layer stack of at least two layers, wherein a transition between a sidewall of an upper layer of the at least two layers and a surface portion of a lower layer of the at least two layers occurs at an angle greater than 95° with respect to a plane (e.g., a horizontal plane). Forming the transition may comprise providing a resist layer; subjecting the resist layer to a pre-treatment processing act (e.g., performing the pre-treatment processing act to process the resist layer); and depositing a metal, such as Cu, e.g., by a patterned growth process, to form the upper layer. The pre-treatment processing act may comprise a wet etch processing act and/or a dry etch processing act.

Further embodiments of methods described above correspond to the embodiments of the power semiconductor device 1 presented above.

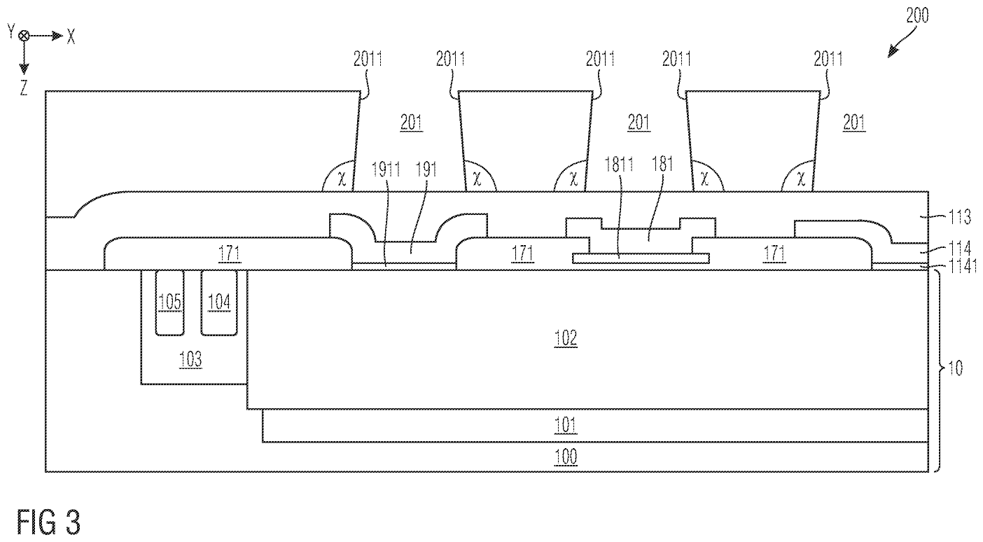

An exemplary method will now be described with respect to FIGS. 3 to 10, each of which illustrating a section of a vertical-cross section of the power semiconductor device that is being processed. There, the semiconductor body 10 has already been fully processed and it may include doped semiconductor regions 100, 101, 102, 103, 104 and 105. Other configurations of regions (e.g., doped semiconductor regions 100, 101, 102, 103, 104 and/or 105) other than those shown in FIGS. 3 to 10 are within the scope of the present disclosure. In some examples, the respective left portion of FIGS. 3 to 10 illustrates a portion of the edge termination region, and the respective right portion of FIGS. 3 to 10 illustrates the beginning of the active region.

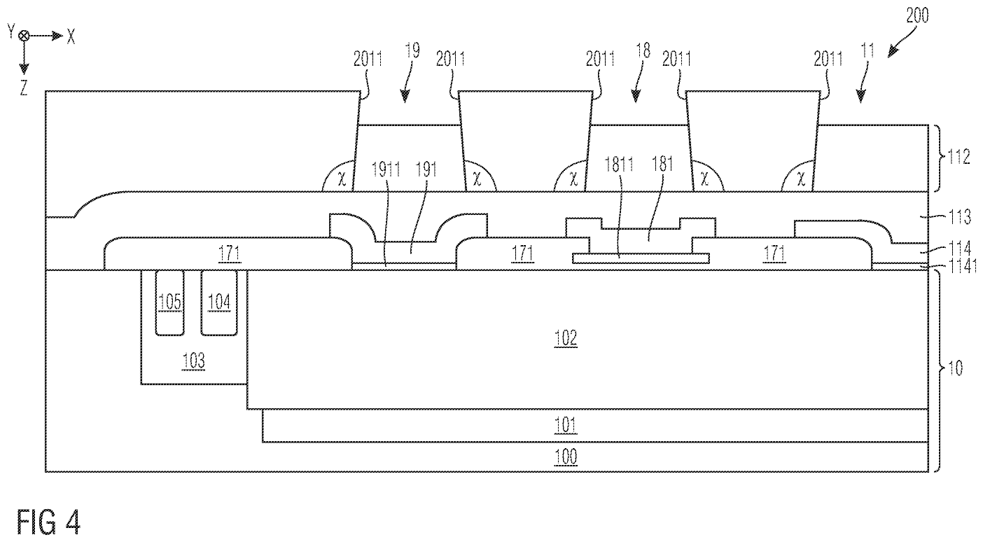

As mentioned with respect to FIG. 1, the further layer 113 can be employed for forming each of the source runner 19, the control runner 18 and the first terminal 11, which may be a load terminal (cf. FIG. 4 et seq.). The further layer 113 may be formed, as illustrated in FIG. 3, so as to cover electrically conductive reception structures 191, 181, 114 of the source runner 19, the control runner 18 and the first terminal 11, respectively. The reception structures 191 and 114 are electrically connected to the doped semiconductor region 102 via conductive coupling layers 1911 and 1141, whereas the reception structure 181 of the control runner 18 rests on a polycrystalline region 1811 electrically isolated from the semiconductor body 10 based on the insulation layer 178.

FIG. 3 illustrates a processing stage where the further layer 113 has been formed as a contiguous layer on top of the reception structures 191, 181 and 114. Further, a resist layer 200 has been provided on top of the further layer 113. The resist layer 200 has been subjected to a processing act, e.g., a lithographic processing act, to form openings 201 at positions corresponding to the portions of the base layer 112 of the later first terminal 11, source runner 19 and control runner 18. The openings 201 expose respective sections of the further layer 113. In an embodiment, the resist layer 200 is processed, such that the openings 201 in the resist layer 200 are defined by respective sidewalls 2011 (e.g., resist layer sidewalls of the resist layer 200) arranged in an angle χ greater than 95° with respect to the horizontal plane. Thereby, the base layer 112 may exhibit base layer sidewalls 1121 extending at said inclination angles α₁ and α₂ smaller than 85°, as exemplarily described with respect to FIG. 1. In some examples, angles χ greater than 95° with respect to the horizontal plane may be achieved by controlling, during processing the resist layer 200, e.g., during lithographic processing the resist layer 200, a focal plane during an exposure of the resist layer 200.

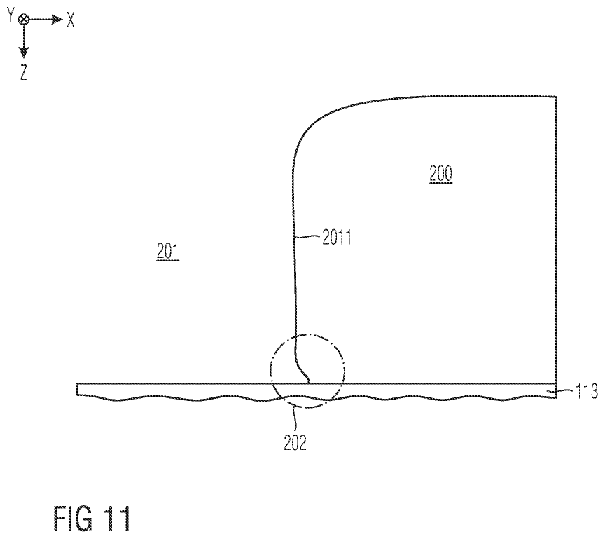

Referring to FIG. 11, in addition to processing the resist layer 200, such that the openings 201 in the resist layer 200 are defined by respective sidewalls 2011 arranged in an angle χ greater than 95° with respect to the horizontal plane, the resist layer 200 may be subjected to a pre-treatment processing act, e.g., comprising a wet etch processing act and/or a dry etch processing act, to produce a cavity 202 at a transition between the opening 201 and the further layer 113. Thereby, when filling the opening 201 in the resist layer with an electrically conductive material, e.g., a metal, to form the base layer 112, said transition 1117 (cf. FIGS. 1 and 2) may be established. For example, forming the base layer 112 includes depositing a metal, such as Cu, e.g., by a patterned growth process, e.g., an electroplating processing act.

The exemplary method will now be further described with respect to FIGS. 4 to 10, wherein it shall be understood that also in accordance with said exemplary method, the above-described pre-treatment processing act may be carried out, even though FIGS. 4 to 10 do not illustrate cavities 202 or, respectively, the transitions 1115 and 1117 as shown in FIG. 11 and FIG. 2, respectively.

At the processing stage illustrated in FIG. 4, the base layer 112 has been formed in resist layer openings 201, e.g., by depositing a metal, such as Cu, e.g., by a patterned growth process, e.g., an electroplating processing act.

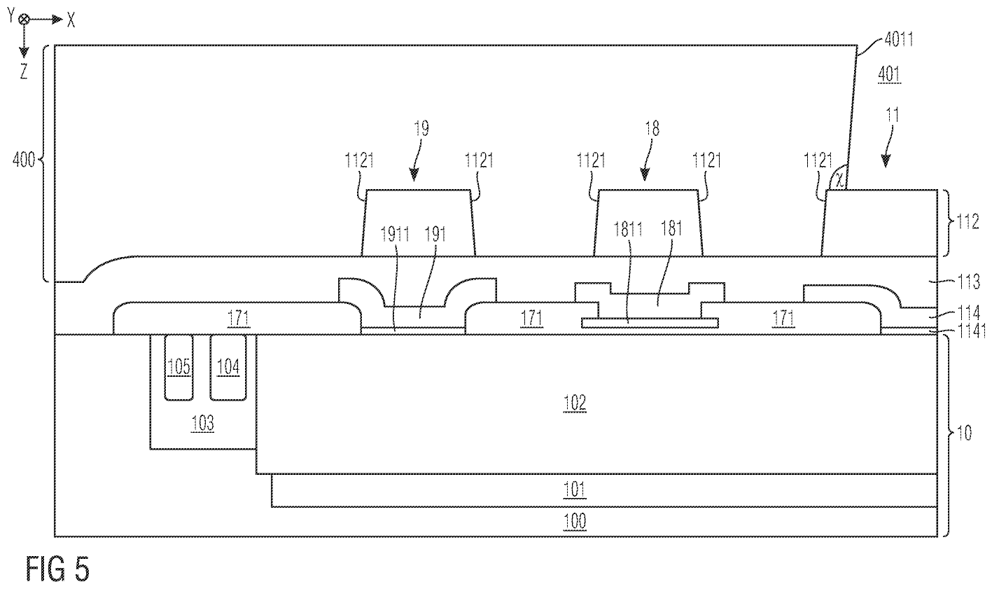

At the processing stage illustrated in FIG. 5, the resist layer 200 has been removed, and a further resist layer 400 with a mask opening 401 at the position corresponding to the later top layer 111 of the first terminal 11 has been provided. Also here, the resist layer 400 may processed such that the mask opening 401 is defined by a sidewall 4011 arranged in an angle χ greater than 95° with respect to a horizontal plane; thereby, it may be ensured that also the sidewall 1111 of the top layer 111 of the first terminal 11 extends at said inclination angle α₁.

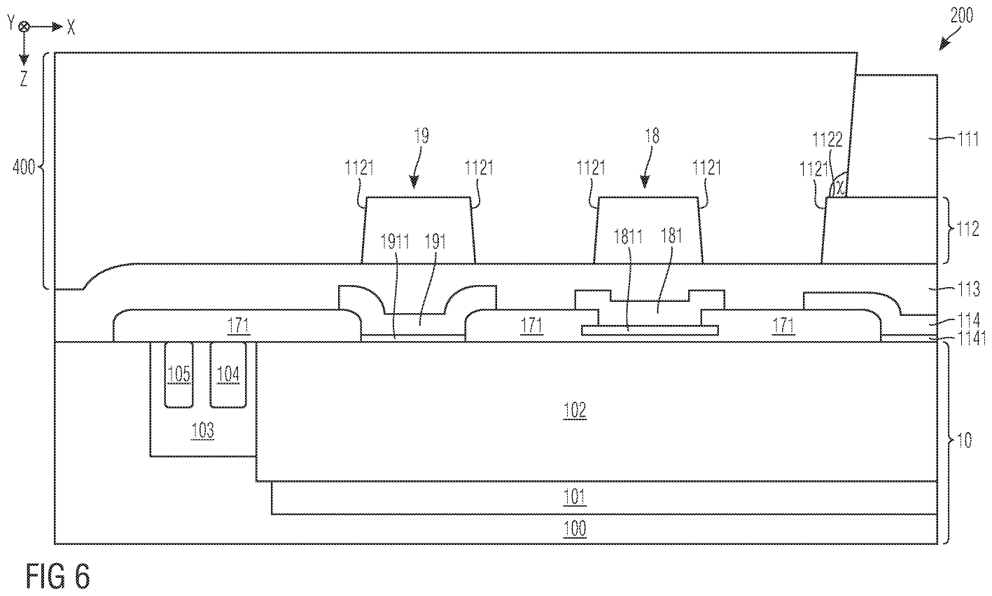

At the processing stage illustrated in FIG. 6, the top layer 111 of the first terminal 11 is formed in further resist layer opening 401, e.g., by depositing a metal, such as Cu, e.g., by a patterned growth process.

As mentioned above, the first terminal 11 may be arranged in the active region. The first terminal 11 may be configured as a terminal pad, e.g., as a terminal pad that is contacted, at the upper surface of the top layer 111, by a bond wire or the like. Several first terminals 11 may be formed as described above, and these first terminals 11 may include both control terminals and load terminals.

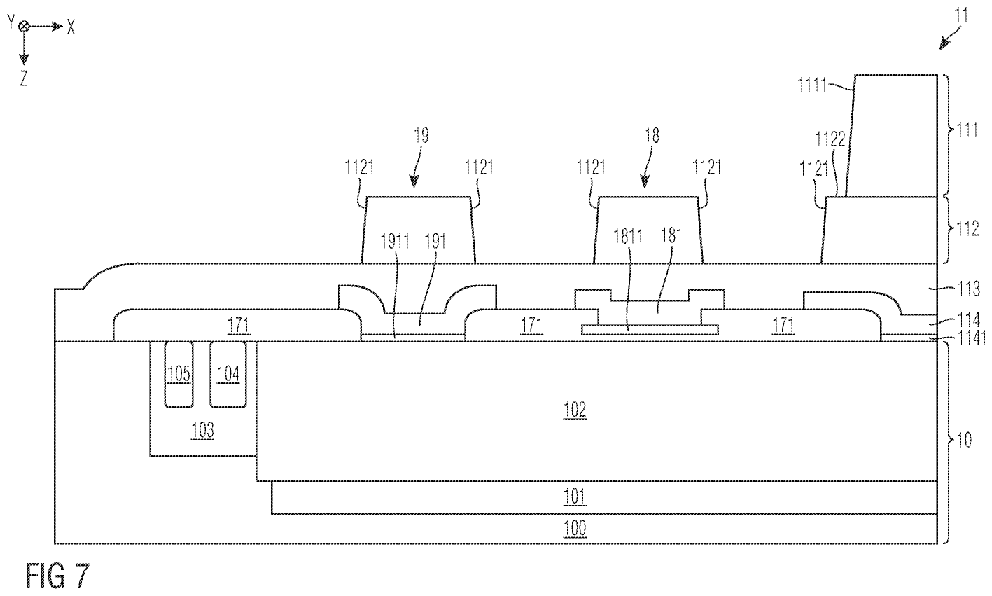

At the processing stage illustrated in FIG. 7, the further resist layer 400 has been removed, thereby exposing the top layer 111 of the first terminal and the base layer 112 and the further layer of the first terminal 11, the control runner 18 and the source runner 19. At this stage, the first terminal 11, the control runner 18 and the source runner 19 are electrically connected with each other due to the contiguous configuration of the further layer 113.

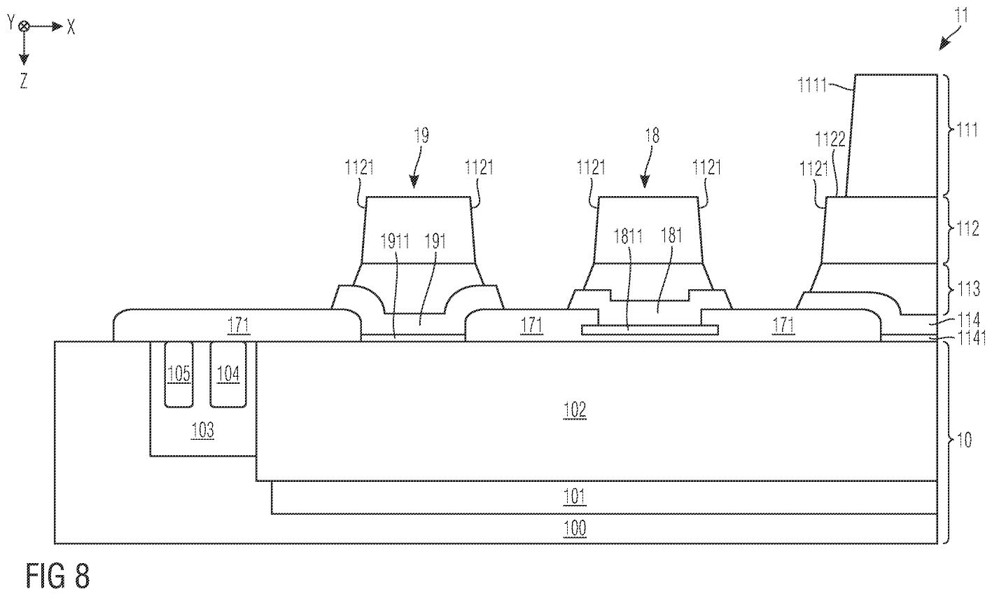

At the processing stage illustrated in FIG. 8, the further layer 113 has been laterally structured, e.g., based on an etching processing act such that the first terminal 11, the control runner 18 and the source runner 19 are electrically separated from each other.

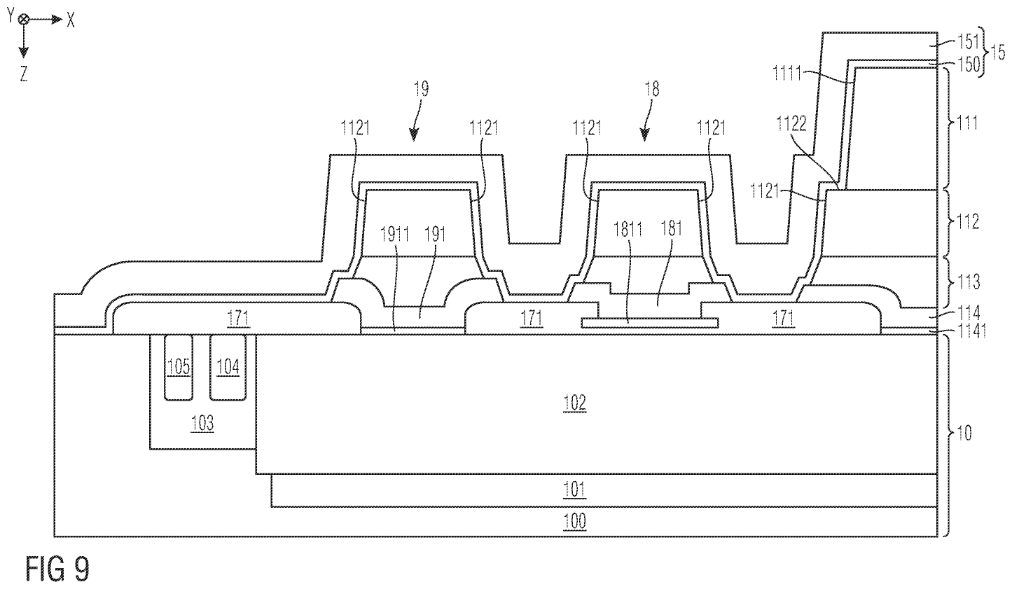

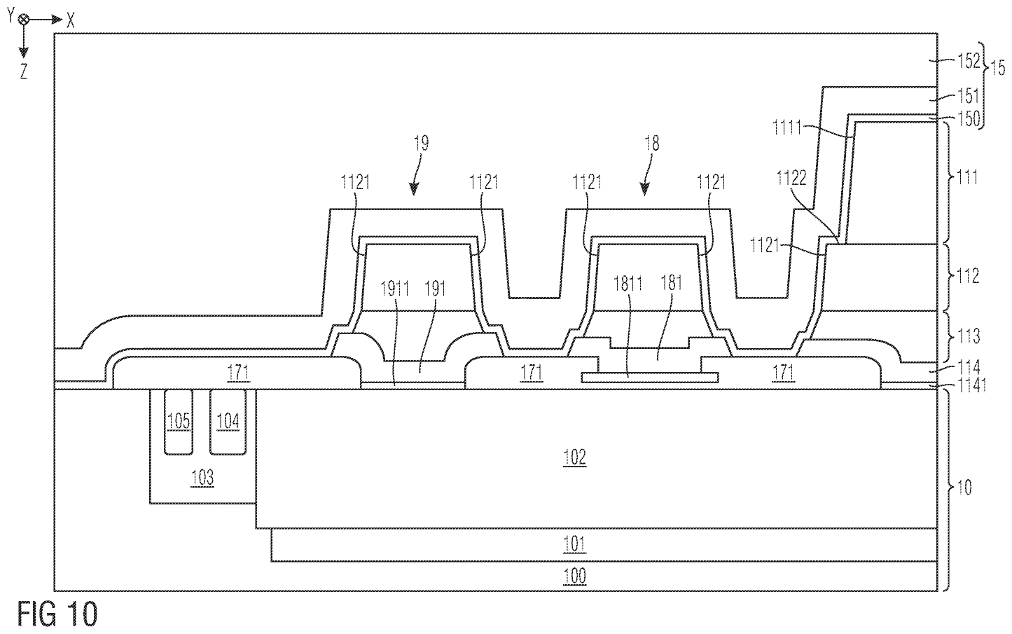

At the processing stages illustrated in FIGS. 9 and 10, the encapsulation 15 has been formed by providing the thin isolating layer 150, the passivation layer 151 to cover the first terminal 11, the control runner 18 and the source runner 19 (cf. FIG. 9). At the processing stage illustrated in FIG. 10, the isolation layer 152 is additionally provided on top of the passivation layer 151.

In the above, embodiments pertaining to a power semiconductor device and corresponding production methods were explained. For example, these power semiconductor devices may comprise (e.g., may be based on) silicon carbide (SiC). Accordingly, a semiconductor region or layer, e.g., the semiconductor body 10 and its regions/zones, e.g., regions etc. can be a SiC-region or SiC-layer.

It should, however, be understood that the semiconductor body 10 and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), aluminum gallium nitride (AlGaN) and aluminum indium nitride (AlInN). For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising”, “exhibiting” and the like are open ended terms that indicate the presence of stated elements or features, but do not preclude additional elements or features.

With the above range of variations and applications in mind, it should be understood that the present invention is not limited by the foregoing description, nor is it limited by the accompanying drawings. Instead, the present invention is limited only by the following claims and their legal equivalents.

1. A power semiconductor device, comprising:
a semiconductor body; and
a first terminal coupled to the semiconductor body, wherein the first terminal has a first side adjoining an encapsulation and a second side adjoining the semiconductor body, the first terminal comprising:
at the first side, a top layer; and
at the second side, a base layer coupled to the top layer, wherein at least one of a sidewall of the top layer or a sidewall of the base layer is arranged in an angle smaller than 85° with respect to a plane.

2. The power semiconductor device of claim 1, wherein at least one of the sidewall of the top layer or the sidewall of the base layer continuously extends at said angle smaller than 85°.

3. The power semiconductor device of claim 1, wherein at least one of the top layer sidewall or the base layer sidewall has a total extension of at least 2 micrometers (μm).

4. The power semiconductor device of claim 1, wherein at least one of the top layer sidewall or the base layer sidewall extends substantially linearly.

5. The power semiconductor device of claim 1, comprising the encapsulation, wherein the encapsulation is coupled to at least one of the top layer sidewall or the base layer sidewall.

6. The power semiconductor device of claim 1, wherein the top layer and the base layer comprise a metal.

7. The power semiconductor device of claim 1, wherein the semiconductor body comprises a semiconductor material.

8. The power semiconductor device of claim 1, wherein at least one of
a first transition, between the top layer sidewall and a surface portion of the base layer, occurs at an angle greater than 95° with respect to the plane; or
a second transition, between the base layer sidewall and a surface portion of a further layer below the base layer, occurs at an angle greater than 95° with respect to the plane.

9. The power semiconductor device of claim 8, wherein at least one of the first transition or the second transition has a vertical extension of at least 400 nanometers (nm) and a lateral extension of at least 250 nm.

10. The power semiconductor device of claim 8, wherein at least one of
the top layer sidewall has an upper portion and a lower portion, the lower portion of the top layer sidewall forming said first transition; or
the base layer sidewall has an upper portion and a lower portion, the lower portion of the base layer sidewall forming said second transition.

11. The power semiconductor device of claim 10, wherein at least one of
the upper portion of the top layer sidewall is arranged in a first angle with respect to the plane, and the lower portion of the top layer sidewall is arranged in a second angle with respect to the plane, wherein the second angle is greater than the first angle; or
the upper portion of the base layer sidewall is arranged in a third angle with respect to the plane, and the lower portion of the base layer sidewall is arranged in a fourth angle with respect to the plane, wherein the fourth angle is greater than the third angle.

12. A power semiconductor device, comprising:
a semiconductor body; and
a first terminal coupled to the semiconductor body, wherein the first terminal has a first side adjoining an encapsulation and a second side adjoining the semiconductor body, the first terminal comprising:
a layer stack of at least two layers, wherein a transition between a sidewall of an upper layer of the at least two layers and a surface portion of a lower layer of the at least two layers occurs at an angle greater than 95° with respect to a plane.

13. The power semiconductor device of claim 12, wherein the transition is formed by a portion of the upper layer.

14. The power semiconductor device of claim 12, wherein the transition has a vertical extension of at least 400 nanometers (nm) and a lateral extension of at least 250 nm.

15. The power semiconductor device of claim 12, wherein each layer of the at least two layers comprises a metal.

16. A method of producing a power semiconductor device, comprising:
forming a semiconductor body; and
forming a first terminal over the semiconductor body, wherein the first terminal has a first side for adjoining an encapsulation and a second side adjoining the semiconductor body, the first terminal comprising:
at the first side, a top layer; and
at the second side, a base layer coupled to the top layer, wherein at least one of a sidewall of the top layer or a sidewall of the base layer is arranged in an angle smaller than 85° with respect to a plane.

17. The method of claim 16, comprising forming the top layer, wherein forming the top layer comprises:
providing a resist layer; and
processing the resist layer comprising forming at least one opening, in the resist layer, defined by a resist layer sidewall arranged in an angle greater than 95° with respect to the plane.

18. The method of claim 17, wherein processing the resist layer comprises:
controlling a focal plane during an exposure of the resist layer to form the resist layer sidewall at said angle greater than 95° with respect to the plane.

19. A method of producing a power semiconductor device, comprising:
forming a semiconductor body; and
forming a first terminal over the semiconductor body, wherein the first terminal has a first side for adjoining an encapsulation and a second side adjoining the semiconductor body, the first terminal comprising:
a layer stack of at least two layers, wherein a transition between a sidewall of an upper layer of the at least two layers and a surface portion of a lower layer of the at least two layers occurs at an angle greater than 95° with respect to a plane.

20. The method of claim 19, comprising forming the transition, wherein forming the transition comprises:
providing a resist layer; and
subjecting the resist layer to a pre-treatment processing act.

21. The method of claim 20, wherein the pre-treatment processing act comprises at least one of a wet etch processing act or a dry etch processing act.

22. The method of claim 19, comprising depositing a metal to form the upper layer.
